(19) United States
(12) Patent Application Publication
(10) Pub. No.: US 2022/0191074 A1
(43) Pub. Date: Jun. 16, 2022

(54) SIGNAL PROCESSING DEVICE, SIGNAL PROCESSING METHOD, AND PROGRAM

(71) Applicant: SONY GROUP CORPORATION, TOKYO (JP)

(72) Inventor: YOSHINORI TAMORI, TOKYO (JP)

(21) Appl. No.: 17/442,977

(22) PCT Filed: Mar. 19, 2020
(86) PCT No.: PCT/JP2020/012198

§ 371 Date: Sep. 24, 2021

(30) Foreign Application Priority Data
Apr. 5, 2019 (JP) 2019-072387

(51) Int. Cl. H04L 25/49; H04R 3/04; H03M 5/08

(52) U.S. Cl. CPC H04L 25/4902; H03M 5/08; H04R 3/04

(57) ABSTRACT

The present technology relates to a signal processing device, a signal processing method, and a program that make it possible to suppress deterioration in audio characteristics. The signal processing device includes: a low-pass filter that performs filter processing on a PDM signal; and a PWM conversion unit that performs PWM conversion on a multibit signal obtained by the filter processing and generates a PWM signal. The present technology can be applied to an audio reproduction system.

### TECHNICAL FIELD

The present technology relates to a signal processing device, a signal processing method, and a program, and more particularly, to a signal processing device, a signal processing method, and a program that are enabled to suppress deterioration in audio characteristics.

### BACKGROUND ART

In recent years, an ultra-high sound quality format called direct stream digital (DSD) has been proposed. In DSD, a tone is digitized by pulse density modulation (PDM), and a PDM signal obtained as a result is treated as an audio signal of a DSD sound source.

For example, in a case where a speaker is driven by a power amplification unit with the PDM signal as it is at the time of reproduction of the DSD sound source, pulse width modulation (PWM) conversion is performed on the PDM signal, and a PWM signal obtained as a result is amplified by the power amplification unit to be input to the speaker.

Furthermore, for example, as a technology relating to the PWM conversion, a technology of canceling switching distortion produced when the power amplification unit is driven with original DSD data as it is by performing the PWM conversion on the DSD data has been proposed (see, for example, Patent Document 1).

### CITATION LIST

### Patent Document

Patent Document 1: Japanese Patent Application Laid-Open No. 2000-68835

### SUMMARY OF THE INVENTION

### Problems to be Solved by the Invention

Incidentally, as described above, when the PWM conversion is performed on the PDM signal and the obtained PWM signal is amplified to drive the speaker, sufficient audio characteristics sometimes have not been obtained.

In other words, in a case where the PWM conversion is performed on the PDM signal, since the frequency of occurrence of narrow pulses in the PWM signal is high, the driving difficulty level of the speaker for the power amplification unit in a subsequent stage rises, and the audio characteristics are likely to decline (deteriorate). In particular, noise is likely to be produced as the driving difficulty level rises.

The present technology has been made in view of such a situation and is intended to make it possible to suppress deterioration in audio characteristics.

### Solutions to Problems

A signal processing device according to one aspect of the present technology includes: a low-pass filter that performs filter processing on a pulse density modulation (PDM) signal; and a pulse width modulation (PWM) conversion unit that performs PWM conversion on a multibit signal obtained by the filter processing and generates a PWM signal.

A signal processing method or a program according to one aspect of the present technology includes: a step of performing filter processing on a PDM signal with a low-pass filter; and a step of performing PWM conversion on a multibit signal obtained by the filter processing and generating a PWM signal.

In one aspect of the present technology, filter processing is performed on a PDM signal by a low-pass filter, PWM conversion is performed on a multibit signal obtained by the filter processing, and a PWM signal is generated.

### BRIEF DESCRIPTION OF DRAWINGS

FIG. 1 is a diagram illustrating a configuration of a general audio reproduction system.

FIG. 2 is a diagram explaining PWM conversion.

FIG. 3 is a diagram explaining PWM conversion.

FIG. 4 is a diagram illustrating a configuration example of an audio reproduction system.

FIG. 5 is a diagram illustrating a configuration example of a low-pass filter.

FIG. 6 is a diagram explaining PWM conversion.

FIG. 7 is a diagram explaining PWM conversion.

FIG. 8 is a flowchart explaining reproduction processing.

FIG. 9 is a diagram illustrating a configuration example of an audio reproduction system.

FIG. 10 is a flowchart explaining reproduction processing.

FIG. 11 is a diagram illustrating a configuration example of a computer.

### MODE FOR CARRYING OUT THE INVENTION

Hereinafter, embodiments to which the present technology is applied will be described with reference to the drawings.

### First Embodiment

<About Reproduction of DSD Sound Source>

The present technology makes it possible to suppress the deterioration in audio characteristics in a case where a power amplification unit handles a signal of a DSD sound source, by performing low-pass filter (LPF) processing on a PDM signal to generate a PDM signal that has been transformed into a multibit structure, in other words, a multibit signal, and performing PWM conversion on the generated PDM signal that has been transformed into a multibit structure.

For example, there are several types of formats of the DSD sound source depending on variations in sampling frequency, but in the following description, the format of the DSD sound source, in other words, the signal of the DSD sound source is assumed as a PDM signal in a form of [64 Fs, 1 bit].

Here, “64 Fs” indicates the sampling frequency of the PDM signal, and “1 bit” indicates the quantization bit depth of the PDM signal, that is, indicates that one sample of the PDM signal is 1-bit information.

In particular, in the following description, since the PDM signal for reproducing a sound (audio) such as music is employed as the signal of the DSD sound source, the sampling frequency is assumed as 1×Fs=44.1 kHz. In addition, although the clock frequency of the master clock of a system necessary for generating the PWM signal has some adopted values within a practical range, 1024 Fs (45.1584 MHz) and 2048 Fs (90.3168 MHz) will be described below as examples.

First, description will be made of a case where the PDM signal of the DSD sound source is not transformed into a multibit structure but is directly subjected to PWM conversion, and the speaker is driven by the power amplification unit on the basis of the obtained PWM signal to reproduce sound.

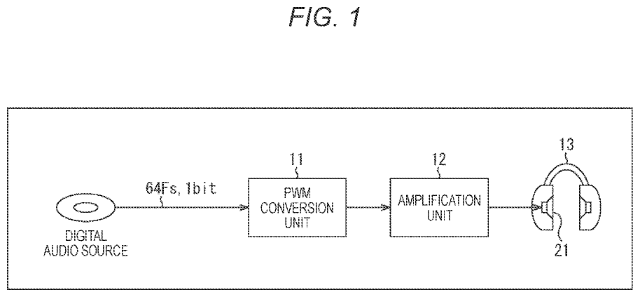

In such a case, a general audio reproduction system for reproducing audio is configured, for example, as illustrated in FIG. 1.

The audio reproduction system illustrated in FIG. 1 is constituted by a PWM conversion unit 11, an amplification unit 12, and headphones 13.

The PWM conversion unit 11 performs PWM conversion on the input PDM signal of the DSD sound source and supplies a PWM signal obtained as a result to the amplification unit 12, which is a power amplification unit.

The PDM signal is a signal in which the amplitude of the audio waveform (temporal waveform) of the sound is expressed in terms of roughness and fineness (density) of the pulse, and the PWM signal is a signal in which the amplitude of the audio waveform of the sound is expressed in terms of the pulse width.

The amplification unit 12 amplifies the PWM signal supplied from the PWM conversion unit 11 and performs digital-to-analog (DA) conversion. Then, the amplification unit 12 drives a speaker 21, in other words, a driver of the headphones 13 on the basis of an analog output signal obtained by the DA conversion to output (reproduce) sound from the speaker 21.

For example, the drive scheme of the speaker 21 (driver) by the amplification unit 12 includes a single-ended drive scheme and a balance drive scheme. Here, a case where the speaker 21 is driven by the balance drive scheme will be specifically described as an example.

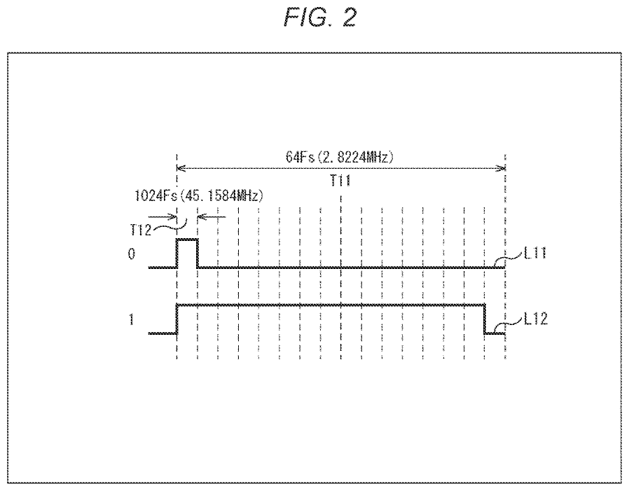

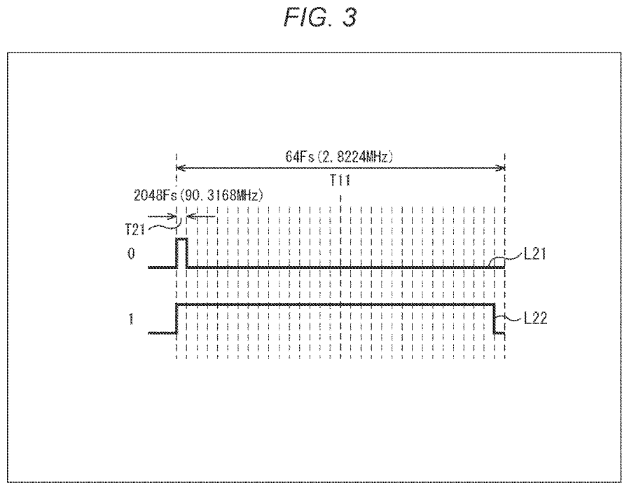

In a case where the speaker 21 is driven in a balanced manner, for example, the PWM conversion illustrated in FIGS. 2 and 3 is performed in the PWM conversion unit 11.

Note that, in FIGS. 2 and 3, the horizontal direction indicates time. Furthermore, FIGS. 2 and 3 illustrate PWM conversion on one side (positive side) of balanced transformer less (BTL). Moreover, in FIGS. 2 and 3, constituent members corresponding to each other are denoted with the same reference signs, and the description thereof will be omitted as appropriate.

FIG. 2 illustrates PWM conversion performed in a case where the clock frequency of the master clock for operating the PWM conversion unit 11 is 1024 Fs.

In this example, a period T11 indicates one sampling period, in other words, a period relevant to one sample of the PDM signal having a sampling frequency of 64 Fs, and a period T12 indicates a period relevant to one clock of the master clock having a clock frequency of 1024 Fs.

In the PDM signal having a sampling frequency of 64 Fs, a value of either “1” or “0”, which is a 1-bit value, is output as a sample value of one sample of the PDM signal every sampling period. The audio waveform of a sound based on the PDM signal is defined depending on the density of the pulse corresponding to the sample value in the time direction. Note that, in order to simplify the explanation, the PWM conversion will be described here as a conversion method for sample values “1” and “0” in one sample.

For example, when the sample value “0” of the PDM signal is supplied to the PWM conversion unit 11, the PWM conversion unit 11 outputs a PWM signal having a waveform indicated by a polygonal line L11 (hereinafter, also referred to as a PWM waveform). The PWM signal indicated by the polygonal line L11 is formed as a pulse signal whose pulse width has a width relevant to the period T12.

In contrast to this, when the sample value “1” of the PDM signal is supplied to the PWM conversion unit 11, the PWM conversion unit 11 outputs a PWM signal having a waveform indicated by a polygonal line L12. The PWM signal indicated by the polygonal line L12 is formed as a pulse signal whose pulse width has a width obtained by subtracting a width relevant to the period T12 from a width relevant to the period T11.

Hereinafter, resolution at which the PWM waveform is fixed will be called “slot”. This resolution is uniquely fixed by the clock frequency of the master clock and the carrier frequency of the PWM signal, in other words, the sampling frequency of the PDM signal.

In the example in FIG. 2, the length of the period T12, which is a period relevant to one clock of the master clock, is regarded as one slot. Furthermore, since the clock frequency of the master clock is 1024 Fs and the sampling frequency of the PDM signal is 64 Fs, the number of slots in one sampling period of the PDM signal is given as 16 (=1024 Fs/64 Fs) slots.

Similarly, in a case where the clock frequency of the master clock is 2048 Fs, PWM conversion is performed as illustrated in FIG. 3.

In other words, for example, when the sample value “0” of the PDM signal is supplied to the PWM conversion unit 11, the PWM conversion unit 11 outputs a PWM signal having a waveform indicated by a polygonal line L21. The PWM signal indicated by the polygonal line L21 is formed as a pulse signal whose pulse width has a width relevant to the period T21.

In contrast to this, when the sample value “1” of the PDM signal is supplied to the PWM conversion unit 11, the PWM conversion unit 11 outputs a PWM signal having a waveform indicated by a polygonal line L22. The PWM signal indicated by the polygonal line L22 is formed as a pulse signal whose pulse width has a width obtained by subtracting a width relevant to the period T12 from a width relevant to the period T11.

In the example in FIG. 3, the length of the period T21, which is a period relevant to one clock of the master clock, is regarded as one slot. Furthermore, since the clock frequency of the master clock is 2048 Fs and the sampling frequency of the PDM signal is 64 Fs, the number of slots in one sampling period of the PDM signal is given as 32 (=2048 Fs/64 Fs) slots.

Now, when attention is paid to the pulse width of the PWM signal indicated by the polygonal line L11 illustrated in FIG. 2, the pulse width of this PWM signal has a width relevant to one slot. Specifically, the pulse width of the PWM signal indicated by the polygonal line L11 is given as 22 (=1/(1024 Fs)) [nsec].

Similarly, the pulse width of the PWM signal indicated by the polygonal line L21 illustrated in FIG. 3 is given as 11 (=1/(2048 Fs)) [nsec].

As can be seen from these examples, the higher the clock frequency of the master clock, the narrower the pulse width of the PWM signal corresponding to the PDM signal whose sample value is “0”.

As described above, in the examples in FIGS. 2 and 3, the minimum pulse width of the PWM signal for driving the speaker 21 is formed as a very narrow width such as 11 [nsec] or 22 [nsec]. Furthermore, the PDM signal for reproducing the DSD sound source is a signal that generates an audio waveform depending on the density of the pulse, and the frequency of occurrence of narrow pulses in the PWM signal is high.

Therefore, in the audio reproduction system illustrated in FIG. 1, the driving difficulty level when the amplification unit 12 drives the speaker 21 is heightened, and as a result, the audio characteristics deteriorate (decline). In other words, noise is produced, and the quality of reproduced sound is degraded.

In particular, in this case, when the speaker 21 is driven by the single-ended drive scheme, the deterioration in audio characteristics is more significant. Therefore, it is often not realistic to adopt the drive by the single-ended drive scheme, and as a result, constraints are applied to the drive scheme of the speaker 21.

Furthermore, in a case where the sampling frequency of the DSD sound source to be reproduced, that is, the PDM signal is high, the clock frequency of the master clock of a system necessary for generating the PWM signal also tends to be high. Accordingly, in such a case, since the minimum pulse width of the PWM signal becomes narrower, the driving difficulty level of the speaker 21 for the amplification unit 12 further rises.

### Configuration Example of Audio Reproduction System

Thus, by performing LPF processing to transform the PDM signal into a multibit structure, the present technology makes it possible to reduce the frequency of occurrence of narrow pulses in the PWM signal and to suppress deterioration in audio characteristics.

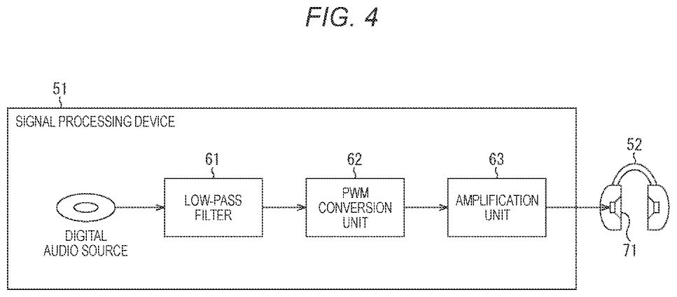

FIG. 4 is a diagram illustrating a configuration example of an embodiment of an audio reproduction system to which the present technology is applied.

The audio reproduction system illustrated in FIG. 4 includes a signal processing device 51 and headphones 52.

The signal processing device 51 is constituted by, for example, an acoustic reproduction control instrument such as a portable player or a smartphone and drives the headphones 52 on the basis of the PWM signal obtained from the PDM signal of the DSD sound source. In other words, the signal processing device 51 outputs an analog output signal obtained from the PWM signal to the headphones 52.

The headphones 52 are driven by the signal processing device 51 and outputs sound from a built-in speaker 71.

Note that the reproduction device to which the output signal obtained by the signal processing device 51 is output is not restricted to the headphones 52 and may be a normal speaker or the like.

In addition, the signal processing device 51 includes a low-pass filter 61, a PWM conversion unit 62, and an amplification unit 63.

A PDM signal, which is an audio signal (digital audio source) for reproducing a sound such as music, is input (supplied) to the low-pass filter 61 from a recording unit (not illustrated) or the like.

The low-pass filter 61 performs, on the input PDM signal, LPF processing that is filter processing of passing only a low-frequency component of the PDM signal, and supplies a multibit signal obtained as a result, in other words, a PDM signal transformed into a multibit structure, to the PWM conversion unit 62.

The PWM conversion unit 62 performs PWM conversion on the PDM signal from the low-pass filter 61, which has been transformed into a multibit structure, to generate a PWM signal, and supplies the obtained PWM signal to the amplification unit 63.

The amplification unit 63 amplifies the PWM signal supplied from the PWM conversion unit 62 to perform DA conversion on the amplified PWM signal, and drives the speaker 71, in other words, the driver of the headphones 52 on the basis of the output signal obtained as a result of the DA conversion, thereby outputting (reproducing) sound from the speaker 71.

Note that the drive scheme used when the amplification unit 63 drives the speaker 71 may be the single-ended drive scheme or the balance drive scheme.

In the signal processing device 51, a power amplification unit (power amplifier) is implemented by the PWM conversion unit 62 and the amplification unit 63. In the hardware configuration of the signal processing device 51, the PWM conversion unit 62 and the amplification unit 63 may be provided on one chip, or the PWM conversion unit 62 and the amplification unit 63 may be provided on chips different from each other.

Furthermore, in the signal processing device 51, a master clock for driving the low-pass filter 61, the PWM conversion unit 62, and the amplification unit 63 is supplied to these blocks, and these blocks operate in accordance with the master clock. For example, 1024 Fs, 2048 Fs, or the like is employed as the clock frequency of the master clock.

### Configuration Example of Low-Pass Filter

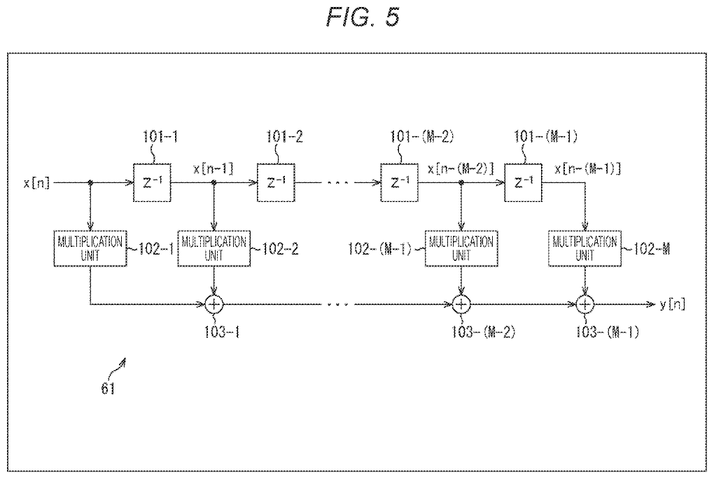

Moreover, the low-pass filter 61 illustrated in FIG. 4 is configured as illustrated in FIG. 5, for example.

In the example illustrated in FIG. 5, the low-pass filter 61 includes a delayer 101-1 to a delayer 101-(M−1), a multiplication unit 102-1 to a multiplication unit 102-M, and an addition unit 103-1 to an addition unit 103-(M−1).

The delayer 101-1 delays the PDM signal input from a recording unit (not illustrated) or the like by a period relevant to one sample of the input PDM signal and then supplies the delayed PDM signal to the delayer 101-2 and the multiplication unit 102-2 in a subsequent stage.

The delayer 101-m (where 2≤m≤M−2 is satisfied) delays the PDM signal supplied from the delayer 101-(m−1) by a period relevant to one sample of the PDM signal and then supplies the delayed PDM signal to the delayer 101-(m+1) and the multiplication unit 102-(m+1) in a subsequent stage.

The delayer 101-(M−1) delays the PDM signal supplied from the delayer 101-(M−2) by a period relevant to one sample of the PDM signal and then supplies the delayed PDM signal to the multiplication unit 102-M in a subsequent stage.

Note that, hereinafter, the delayers 101-1 to 101-(M−1) will also be simply referred to as delayers 101 in a case where it is not particularly necessary to distinguish between the delayers 101-1 to 101-(M−1).

Furthermore, in FIG. 5, x[n] indicates the sample value of the n-th sample from the beginning of the PDM signal, and y[n] indicates the sample value of the n-th sample from the beginning of the PDM signal transformed into a multibit structure, which is the output of the low-pass filter 61.

The multiplication unit 102-1 multiplies the PDM signal input from a recording unit (not illustrated) or the like by a held coefficient (hereinafter, also referred to as a tap coefficient) of the LPF and supplies the PDM signal multiplied by the tap coefficient to the addition unit 103-1 in a subsequent stage.

The multiplication unit 102-m (where 2≤m≤M is satisfied) multiplies the PDM signal supplied from the delayer 101-(m−1) by the held tap coefficient and supplies the PDM signal multiplied by the tap coefficient to the addition unit 103-(m−1) in a subsequent stage.

Note that, hereinafter, the multiplication units 102-1 to 102-M are also simply referred to as multiplication units 102 in a case where it is not particularly necessary to distinguish between the multiplication units 102-1 to 102-M.

The addition unit 103-1 adds the PDM signal supplied from the multiplication unit 102-1 and the PDM signal supplied from the multiplication unit 102-2 and supplies the added PDM signals to the addition unit 103-2 in a subsequent stage.

The addition unit 103-m (where 2≤m≤M−2 is satisfied) adds the PDM signal supplied from the addition unit 103-(m−1) and the PDM signal supplied from the multiplication unit 102-(m+1) and supplies the added PDM signals to the addition unit 103-(m+1) in a subsequent stage.

The addition unit 103-(M−1) adds the PDM signal supplied from the addition unit 103-(M−2) and the PDM signal supplied from the multiplication unit 102-M and supplies a signal y[n] obtained as a result to the PWM conversion unit 62 as a PDM signal transformed into a multibit structure.

Note that, hereinafter, the addition units 103-1 to 103-(M−1) are also simply referred to as addition units 103 in a case where it is not particularly necessary to distinguish between the addition units 103-1 to 103-(M−1).

In such a low-pass filter 61, the number M of multiplication units 102 represents the number of taps of the low-pass filter 61, that is, the LPF.

In the present technology, the tap coefficient in each multiplication unit 102 and the number of taps M are appropriately assigned according to the combination of the sampling frequency of the PDM signal and the clock frequency of the master clock.

Specifically, assuming that the number of slots in one sampling period of the PDM signal is SL, for example, M=(SL−1) is employed as the number of taps M.

In other words, the low-pass filter 61 is configured with (SL−2) delayers 101 and addition units 103 and (SL−1) multiplication units 102.

For example, in a case where the PDM signal that is the input of the low-pass filter 61 is a signal of [64 Fs, 1 bit] and the clock frequency of the master clock is 1024 Fs, the PDM signal transformed into a multibit structure, which is the output of the low-pass filter 61, is given as a signal of [64 Fs, 4 bits].

In other words, a signal having a sampling frequency of 64 Fs and four bits per sample is output from the low-pass filter 61 as the PDM signal transformed into a multibit structure.

In contrast to this, for example, in a case where the PDM signal that is the input of the low-pass filter 61 is a signal of [64 Fs, 1 bit] and the clock frequency of the master clock is 2048 Fs, the PDM signal transformed into a multibit structure, which is the output of the low-pass filter 61, is given as a signal of [64 Fs, 5 bits].

In other words, a signal having a sampling frequency of 64 Fs and five bits per sample is output from the low-pass filter 61 as the PDM signal transformed into a multibit structure.

In this case, regardless of whether the clock frequency of the master clock is 1024 Fs or 2048 Fs, the sampling frequency of the PDM signal transformed into a multibit structure, which is obtained as a result of the LPF processing, remains at 64 Fs, which is the same as the sampling frequency of the original PDM signal.

For example, in a case where the clock frequency of the master clock is 1024 Fs, since the number of slots SL is SL=16, the PWM conversion unit 62 can perform PWM conversion on a signal of up to four bits per sample.

If a signal has five bits or more per sample of the PDM signal transformed into a multibit structure in a case where the number of slots SL is 16, it is necessary to provide a ΔΣ modulator between the low-pass filter 61 and the PWM conversion unit 62 in order to reduce the bit depth per sample of the signal input to the PWM conversion unit 62.

In consequence, not only the circuit scale is expanded by the ΔΣ modulator, but also quantization noise is appended to the PDM signal due to the ΔΣ modulation in the ΔΣ modulator, which deteriorates audio characteristics.

In contrast to this, in the signal processing device 51, the number of taps M is appropriately designated (selected) on the basis of the sampling frequency of the PDM signal and the clock frequency of the master clock, that is, the number of slots SL. Specifically, for example, the number of taps M=(SL−1) is employed.

In this case, for example, when the clock frequency of the master clock is 1024 Fs, one sample of the PDM signal transformed into a multibit structure, which is the output of the low-pass filter 61, has four bits, such that the output of the low-pass filter 61 can be directly subjected to PWM conversion.

Similarly, for example, in a case where the clock frequency of the master clock is 2048 Fs, since the number of slots SL is SL=32, the PWM conversion unit 62 can perform PWM conversion on a signal of up to five bits per sample. In this case, since one sample of the PDM signal transformed into a multibit structure, which is the output of the low-pass filter 61, has five bits, this five-bit signal can be directly subjected to PWM conversion.

By configuring in this manner, it is no longer necessary to provide a ΔΣ modulator in the signal processing device 51 and, accordingly the circuit scale can be shrunk. Besides, in the low-pass filter 61, by appropriately designating the number of taps M, the PDM signal can be normalized to a maximum value within specified bits at all times, and accordingly the signal level of the PDM signal transformed into a multibit structure does not deteriorate. Furthermore, since quantization noise is not appended to the PDM signal transformed into a multibit structure, the deterioration in audio characteristics can be suppressed.

Note that, since the LPF processing is performed on the PDM signal in the signal processing device 51, level fluctuations are produced in a high frequency of the PDM signal. However, the level fluctuations do not affect the audible band of the PDM signal, and accordingly a listener hardly feels the degradation of the audio characteristics when the sound is reproduced by the headphones 52.

In particular, by assigning the tap coefficient in each multiplication unit 102 according to the combination of the sampling frequency of the PDM signal and the clock frequency of the master clock, desired characteristics can be obtained as the frequency characteristics of the low-pass filter 61. Accordingly, if the tap coefficients are appropriately assigned, the PDM signal can be transformed into a multibit structure without degrading the audio characteristics in the audible band.

Specifically, for example, if the value of the tap coefficient in each multiplication unit 102 is assumed as “1”, the low-pass filter 61 serves as a moving average filter.

Besides, by performing the LPF processing on the PDM signal in the low-pass filter 61, shaping noise (high-frequency noise) inherent to the DSD sound source, that is, originally included in the PDM signal can be reduced, and audio characteristics can be improved.

<About PWM Conversion>

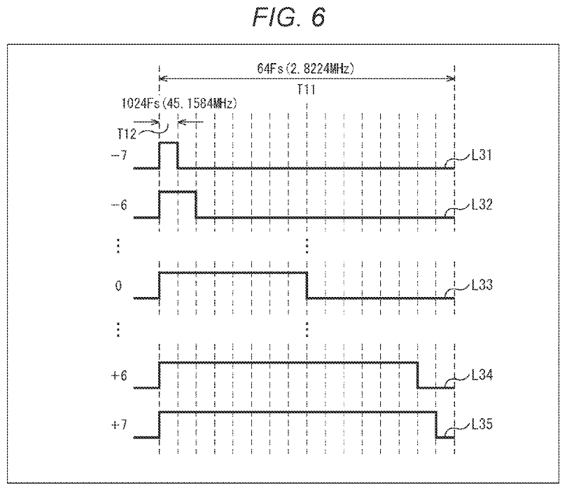

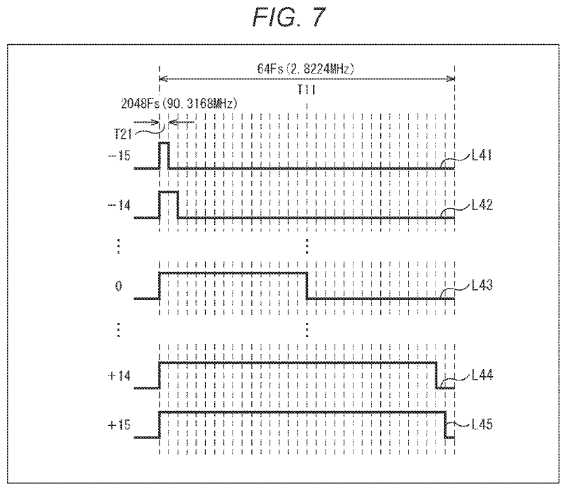

Next, a specific example of the PWM conversion performed in the PWM conversion unit 62 will be described with reference to FIGS. 6 and 7.

Note that, in FIGS. 6 and 7, the horizontal direction indicates time. Furthermore, FIGS. 6 and 7 illustrate PWM conversion on one side (positive side) of the BTL. Moreover, in FIGS. 6 and 7, constituent members corresponding to those in the case of FIGS. 2 and 3 are denoted with the same reference signs, and the description thereof will be omitted as appropriate.

FIG. 6 illustrates PWM conversion performed in a case where the clock frequency of the master clock for operating the PWM conversion unit 62 is 1024 Fs.

The PDM signal transformed into a multibit structure to be input to the PWM conversion unit 62 is a signal having four bits per sample, and for example, the sample value of one sample takes any value from −7 to +7.

For example, when the sample value “−7” of the PDM signal transformed into a multibit structure is supplied to the PWM conversion unit 62, the PWM conversion unit 62 outputs a PWM signal having a waveform indicated by a polygonal line L31. The PWM signal indicated by the polygonal line L31 is formed as a pulse signal whose pulse width has a width relevant to the period T12, that is, relevant to one slot.

Furthermore, for example, when the sample value “−6” of the PDM signal transformed into a multibit structure is supplied to the PWM conversion unit 62, the PWM conversion unit 62 outputs a PWM signal having a waveform indicated by a polygonal line L32. The PWM signal indicated by the polygonal line L32 is formed as a pulse signal whose pulse width has a width relevant to two slots.

Similarly, when the sample value “0” of the PDM signal transformed into a multibit structure is supplied to the PWM conversion unit 62, the PWM conversion unit 62 outputs a PWM signal having a waveform indicated by a polygonal line L33. The PWM signal indicated by the polygonal line L33 is formed as a pulse signal whose pulse width has a width relevant to eight slots.

Moreover, for example, when the sample values “+6” and “+7” of the PDM signal transformed into a multibit structure are individually supplied to the PWM conversion unit 62, the PWM conversion unit 62 outputs PWM signals having waveforms indicated by polygonal lines L34 and L35, respectively.

The PWM signals indicated by the polygonal lines L34 and L35 are formed as pulse signals whose pulse widths have widths relevant to 14 slots and relevant to 15 slots, respectively.

Similarly, in a case where the clock frequency of the master clock is 2048 Fs, PWM conversion is performed as illustrated in FIG. 7.

In this case, the PDM signal transformed into a multibit structure to be input to the PWM conversion unit 62 is a signal having five bits per sample, and for example, the sample value of one sample takes any value from −15 to +15.

For example, when the sample value “−15” of the PDM signal transformed into a multibit structure is supplied to the PWM conversion unit 62, the PWM conversion unit 62 outputs a PWM signal having a waveform indicated by a polygonal line L41. The PWM signal indicated by the polygonal line L41 is formed as a pulse signal whose pulse width has a width relevant to the period T21, that is, relevant to one slot.

Furthermore, for example, when the sample value “−14” of the PDM signal transformed into a multibit structure is supplied to the PWM conversion unit 62, the PWM conversion unit 62 outputs a PWM signal having a waveform indicated by a polygonal line L42. The PWM signal indicated by the polygonal line L42 is formed as a pulse signal whose pulse width has a width relevant to two slots.

Similarly, when the sample value “0” of the PDM signal transformed into a multibit structure is supplied to the PWM conversion unit 62, the PWM conversion unit 62 outputs a PWM signal having a waveform indicated by a polygonal line L43. The PWM signal indicated by the polygonal line L43 is formed as a pulse signal whose pulse width has a width relevant to 16 slots.

Moreover, for example, when the sample values “+14” and “+15” of the PDM signal transformed into a multibit structure are individually supplied to the PWM conversion unit 62, the PWM conversion unit 62 outputs PWM signals having waveforms indicated by polygonal lines L44 and L45, respectively.

The PWM signals indicated by the polygonal lines L44 and L45 are formed as pulse signals whose pulse widths have widths relevant to 30 slots and relevant to 31 slots, respectively.

Note that, although the PWM conversion on the positive side of the BTL has been described with reference to FIGS. 6 and 7, the PWM signal can also be obtained in PWM conversion on a negative side of the BTL or in PWM conversion in a case where the speaker 71 is driven in single-ended drive in a manner similar to the case of the positive side of the BTL.

As described above, in the signal processing device 51, the PDM signal transformed into a multibit structure is targeted at the time of PWM conversion, and level information on the signal (audio waveform), that is, the amplitude is converted into time information on the pulse width, which is a feature of the PWM signal.

Therefore, for example, in the PWM conversion illustrated in FIGS. 6 and 7, it can be seen that the frequency of occurrence of narrow pulses is extremely decreased as compared with the example illustrated in FIGS. 2 and 3.

For this reason, in the signal processing device 51, the driving difficulty level of the speaker 71 for the amplification unit 63 can be lowered, and the deterioration in audio characteristics of the output signal output from the amplification unit 63 can be suppressed.

Besides, in the signal processing device 51, the deterioration in audio characteristics can be easily suppressed by small-scale circuit addition of adding the low-pass filter 61.

Furthermore, since the sampling frequency of the PDM signal does not change between before and after the input to the low-pass filter 61, that is, there is no need to lower the sampling frequency, information inherent in the original DSD sound source can be held.

Moreover, in the signal processing device 51, since the driving difficulty level of the speaker 71 can be lowered and the deterioration in audio characteristics can be suppressed, not only the balance drive scheme but also the single-ended drive scheme can be adopted as the drive scheme for the speaker 71. In other words, the degree of freedom in driving the speaker 71 can be improved.

Additionally, in the signal processing device 51, by appropriately assigning the number of taps and the tap coefficients of the low-pass filter 61, an increase in the circuit scale due to the addition of a ΔΣ modulator or the like can be prevented, and quantization noise is not appended to the PDM signal.

Moreover, by performing the LPF processing in the low-pass filter 61, shaping noise included in the PDM signal can be reduced, and audio characteristics can be improved.

<Description of Reproduction Processing>

Subsequently, an operation of the audio reproduction system illustrated in FIG. 4 will be described.

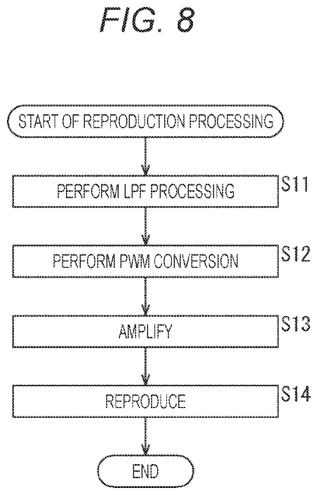

When an instruction to reproduce music or the like is given, the audio reproduction system performs reproduction processing to reproduce the instructed music or the like. Hereinafter, the reproduction processing by the audio reproduction system will be described with reference to the flowchart in FIG. 8.

When the reproduction processing is started, a PDM signal of specified music or the like is read and input to the low-pass filter 61.

In step S11, the low-pass filter 61 performs the LPF processing on the input PDM signal and supplies the PDM signal transformed into a multibit structure, which has been obtained as a result the LPF processing, to the PWM conversion unit 62.

For example, in a case where the low-pass filter 61 is configured as illustrated in FIG. 5, each delayer 101 delays the supplied PDM signal relevant to one sample and supplies the delayed PDM signal to the delayer 101 and the multiplication unit 102 in a subsequent stage. Furthermore, each multiplication unit 102 multiplies the PDM signal supplied from the delayer 101 or the like by the tap coefficient and supplies the PDM signal multiplied by the tap coefficient to the addition unit 103 in a subsequent stage. Moreover, each addition unit 103 adds the PDM signals supplied from the multiplication unit 102 and the addition unit 103 in a preceding stage and outputs the added PDM signals to a subsequent stage.

This causes a multibit signal according to the number of slots to be supplied to the PWM conversion unit 62.

In step S12, the PWM conversion unit 62 performs PWM conversion on the PDM signal transformed into a multibit structure, which has been supplied from the low-pass filter 61, and supplies the PWM signal obtained as a result to the amplification unit 63. For example, in step S12, the PWM conversion is performed as described with reference to FIGS. 6 and 7.

In step S13, the amplification unit 63 amplifies the PWM signal supplied from the PWM conversion unit 62 and also performs DA conversion on the PWM signal after the amplification.

In step S14, the amplification unit 63 drives the speaker 71 provided in the headphones 52 on the basis of the analog output signal obtained by the DA conversion and causes the speaker 71 to reproduce music or the like. When the music or the like is reproduced, the reproduction processing ends.

In the manner described above, the audio reproduction system performs the LPF processing on the PDM signal and performs the PWM conversion on the PDM signal transformed into a multibit structure to generate the PWM signal. By processing in this manner, the frequency of occurrence of narrow pulses can be reduced and the deterioration in audio characteristics can be suppressed.

### Second Embodiment

### Configuration Example of Audio Reproduction System

Incidentally, depending on the sampling frequency and the number of slots SL of the PDM signal described above, the actual measurement result of the audio characteristics, information regarding the speaker 71 (driver), and the like, sufficient audio characteristics can be obtained in some cases without performing the LPF processing on the PDM signal.

In a case where the LPF processing is not performed, power consumption and the amount of processing can be kept small as compared with a case where the LPF processing is performed. Thus, for example, it may be determined whether or not to perform the LPF processing for each piece of content such as music or for each reproduction section, and the music or the like may be reproduced according to the result of the determination.

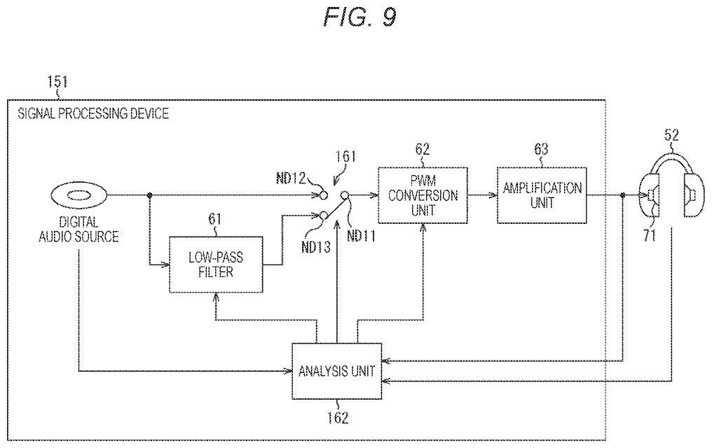

In such a case, the audio reproduction system is configured, for example, as illustrated in FIG. 9. Note that, in FIG. 9, constituent members corresponding to those in the case of FIG. 4 are denoted with the same reference signs, and the description thereof will be omitted as appropriate.

An audio reproduction system illustrated in FIG. 9 includes a signal processing device 151 and headphones 52. The signal processing device 151 corresponds to the signal processing device 51 illustrated in FIG. 4.

In FIG. 9, the signal processing device 151 includes a low-pass filter 61, a switch 161, a PWM conversion unit 62, an amplification unit 63, and an analysis unit 162.

The switch 161 is controlled by the analysis unit 162 and switches the input source of a signal to the PWM conversion unit 62 by switching the connection destination of a node ND11 connected to an input end of the PWM conversion unit 62 to a node ND12 or a node ND13.

In different terms, the switch 161 functions as a switching unit that switches whether to supply a PDM signal not transformed into a multibit structure to the PWM conversion unit 62 or to supply a PDM signal transformed into a multibit structure to the PWM conversion unit 62, under the control of the analysis unit 162.

For example, in a state in which the node ND11 is connected to the node ND12, the PDM signal read from a recording unit (not illustrated) or the like is directly supplied to the PWM conversion unit 62 via the switch 161.

On the other hand, in a state in which the node ND11 is connected to the node ND13, the PDM signal transformed into a multibit structure, which has been output from the low-pass filter 61, is supplied to the PWM conversion unit 62 via the switch 161.

The analysis unit 162 controls the operations of the low-pass filter 61, the switch 161, and the PWM conversion unit 62 on the basis of sound source information supplied from a recording unit (not illustrated) or the like, an analog output signal output from the amplification unit 63, and driver information supplied from the headphones 52.

For example, the sound source information is formed as information indicating the whole PDM signal, the sampling frequency of the PDM signal, or the like. Furthermore, the driver information is information regarding the speaker 71 (driver) and, for example, is an impedance value in the speaker 71, drive scheme information indicating the drive scheme of the speaker 71, or the like. In general, when the amplification unit 63 and the speaker 71 are electrically connected, the analysis unit 162 can recognize the drive scheme of the speaker 71. In other words, the drive scheme information as the driver information can be obtained.

Here, a specific example of control of the low-pass filter 61, the switch 161, and the PWM conversion unit 62 by the analysis unit 162 will be described.

For example, the analysis unit 162 can work out the above-described number of slots SL from the sampling frequency of the PDM signal indicated by the sound source information and the known clock frequency of the master clock and designate the number of taps and the tap coefficients of the low-pass filter 61 on the basis of the obtained number of slots SL.

In this case, the analysis unit 162 supplies information indicating the designated number of taps and tap coefficients to the low-pass filter 61 and causes the low-pass filter 61 to execute the LPF processing with a filter configuration defined by the supplied number of taps and tap coefficients.

Furthermore, for example, on the basis of the output value of the amplification unit 63, in other words, an analog output signal that is the output to the speaker 71 from the amplification unit 63, the analysis unit 162 may work out audio characteristics of that output signal and control node switching by the switch 161 on the basis of the obtained audio characteristics. In different terms, the driving difficulty level of the speaker 71 may be recognized on the basis of the audio characteristics, and the switch 161 may be controlled according to the result of the recognition.

Specifically, for example, the analysis unit 162 works out, as the audio characteristics, a noise level or a distortion level, that is, the magnitude of noise or distortion of the output signal output from the amplification unit 63 on the basis of that output signal. At this time, in a case where there are many noises and distortions, it is supposed to be preferable to perform the PWM conversion on the multibit signal obtained by the LPF processing in order to ensure sufficient audio characteristics.

Thus, in a case where the worked-out noise level or distortion level is equal to or greater than a threshold value assigned in advance, the analysis unit 162 connects the node ND11 of the switch 161 to the node ND13 and allows the PDM signal transformed into a multibit structure to be supplied to the PWM conversion unit 62.

In contrast to this, in a case where the worked-out noise level or distortion level is less than the threshold value assigned in advance, the analysis unit 162 connects the node ND11 of the switch 161 to the node ND12 and allows the PDM signal not transformed into a multibit structure to be supplied to the PWM conversion unit 62.

Furthermore, for example, the analysis unit 162 may control node switching by the switch 161 on the basis of the driver information supplied from the headphones 52. In different terms, the driving difficulty level of the speaker 71 may be recognized on the basis of the driver information, and the switch 161 may be controlled according to the result of the recognition.

Specifically, for example, in a case where the impedance value as the driver information supplied from the headphones 52 is equal to or greater than a threshold value assigned in advance, the analysis unit 162 connects the node ND11 of the switch 161 to the node ND13 and allows the PDM signal transformed into a multibit structure to be supplied to the PWM conversion unit 62.

This is because, in a case where the impedance value of the speaker 71 is high, the voltage of the DA output signal of the amplification unit 63 has to be raised in order to output sound with a necessary and sufficient sound pressure from that speaker 71, and the driving difficulty level of the speaker 71 is heightened. In this case, it is preferable to perform the PWM conversion on the multibit signal obtained by the LPF processing in order to ensure sufficient audio characteristics.

In contrast to this, in a case where the impedance value is less than the threshold value assigned in advance, the analysis unit 162 connects the node ND11 of the switch 161 to the node ND12 and allows the PDM signal not transformed into a multibit structure to be supplied to the PWM conversion unit 62.

As described above, in a case where the driving difficulty level of the speaker 71 is low and sufficient audio characteristics can be ensured, the analysis unit 162 connects the node ND11 to the node ND12 and allows the PWM conversion to be performed on the PDM signal not transformed into a multibit structure. This makes it possible to reduce the amount of processing and power consumption in the entire signal processing device 151 while ensuring sufficient audio characteristics.

Note that, although the example of controlling the switch 161 on the basis of the output value of the amplification unit 63 and the example of controlling the switch 161 on the basis of the driver information have been described here, these examples may be combined to control the switch 161 on the basis of the output value of the amplification unit 63 and the driver information.

Additionally, for example, the analysis unit 162 can control the PWM conversion in the PWM conversion unit 62 according to the drive scheme information as the driver information, the connection status of the switch 161, the sound source information, and the like.

In such a case, for example, the analysis unit 162 generates setting information indicating a setting when PWM conversion is performed by the PWM conversion unit 62, according to the drive scheme indicated by the drive scheme information as the driver information, and the like, and supplies the generated setting information to the PWM conversion unit 62. The PWM conversion unit 62 performs the PWM conversion in accordance with setting indicated by the setting information supplied from the analysis unit 162.

Specifically, for example, it is assumed that the drive scheme indicated by the drive scheme information as the driver information is the balance drive scheme, and the node ND11 is connected to the node ND13.

Furthermore, it is assumed that the sampling frequency of the PDM signal recognized from the sound source information is 64 Fs, and the number of slots SL is 16. In other words, it is assumed that a PDM signal of [64 Fs, 4 bits] transformed into a multibit structure is input to the PWM conversion unit 62.

In such a case, the analysis unit 162 generates setting information for performing the PWM conversion described with reference to FIG. 6 and supplies the generated setting information to the PWM conversion unit 62.

It is assumed, as an example, that the PWM conversion unit 62 holds a conversion table for performing PWM conversion assigned for a combination of the number of slots SL and the drive scheme, for each combination of the number of slots SL and the drive scheme indicated by the drive scheme information, for example.

For example, in the conversion table, a sample value of the input PDM signal is associated with a waveform (pulse width) of the PWM signal expected to be output with respect to that sample value. Specifically, for example, in the example illustrated in FIG. 6, the PWM waveform indicated by the polygonal line L31 is associated with the sample value “−7”.

In this case, the analysis unit 162 generates identification information indicating a conversion table as setting information and supplies the generated setting information to the PWM conversion unit 62. In response to the above, the PWM conversion unit 62 selects the conversion table on the basis of the setting information supplied from the analysis unit 162 and performs PWM conversion using the selected conversion table.

By processing in this manner, the analysis unit 162 can control the PWM conversion unit 62 such that appropriate PWM conversion is performed according to the headphones 52 connected to the signal processing device 151 or the DSD sound source to be reproduced.

<Description of Reproduction Processing>

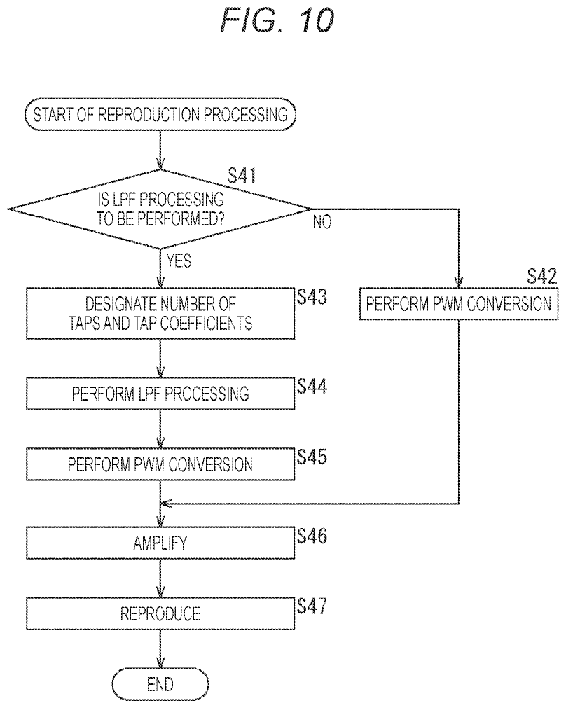

Here, reproduction processing performed by the audio reproduction system illustrated in FIG. 9 will be described. In other words, the reproduction processing performed by the audio reproduction system will be described below with reference to the flowchart in FIG. 10.

In step S41, the analysis unit 162 determines whether or not to perform the LPF processing on the basis of at least one of the analog output signal output from the amplification unit 63 or the driver information supplied from the headphones 52.

For example, in step S41, in a case where the impedance value as the driver information is equal to or greater than a threshold value assigned in advance, it is determined that the LPF processing is to be performed.

In a case where it is determined in step S41 that the LPF processing is not to be performed, the analysis unit 162 controls the switch 161 to connect the node ND11 to the node ND12, and the processing proceeds to step S42 thereafter.

Furthermore, at this time, the analysis unit 162 generates the setting information according to the drive scheme information as the driver information supplied from the headphones 52, and the like and supplies the generated setting information to the PWM conversion unit 62.

In step S42, in accordance with the setting information supplied from the analysis unit 162, the PWM conversion unit 62 performs PWM conversion on the PWM signal not transformed into a multibit structure, which has been supplied via the switch 161, and supplies the PWM signal obtained as a result to the amplification unit 63. For example, in step S42, the PWM conversion is performed as described with reference to FIGS. 2 and 3.

Once the PWM conversion is performed, the processing proceeds to step S46 thereafter.

In contrast to this, in a case where it is determined in step S41 that the LPF processing is to be performed, the analysis unit 162 controls the switch 161 to connect the node ND11 to the node ND13, and the processing proceeds to step S43 thereafter.

Furthermore, at this time, the analysis unit 162 generates the setting information according to the drive scheme information as the driver information supplied from the headphones 52, and the like and supplies the generated setting information to the PWM conversion unit 62.

In step S43, the analysis unit 162 designates the number of taps and the tap coefficients of the low-pass filter 61 on the basis of the supplied sound source information and supplies information indicating the designated number of taps and tap coefficients to the low-pass filter 61.

Once the processing in step S43 is performed, the processing in steps S44 and S45 is performed thereafter, but, since these pieces of processing are similar to the pieces of processing in steps S11 and S12 in FIG. 8, the description thereof will be omitted.

However, in step S44, the low-pass filter 61 performs the LPF processing on the supplied PDM signal with the number of taps and the tap coefficients indicated by the information supplied from the analysis unit 162 and supplies the multibit signal obtained as a result to the PWM conversion unit 62 via the switch 161. Furthermore, in step S45, the PWM conversion unit 62 performs the PWM conversion in accordance with the setting information supplied from the analysis unit 162.

When the processing in step S45 is performed or the processing in step S42 is performed, the processing in steps S46 and S47 are performed thereafter, and the reproduction processing ends. Note that these pieces of processing in steps S46 and S47 are similar to the processing in steps S13 and S14 in FIG. 8, and thus the description thereof will be omitted.

In the manner described above, the audio reproduction system controls the low-pass filter 61 and the PWM conversion unit 62 according to the sound source information and the driver information and also controls the switch 161 according to the output value of the amplification unit 63 and the driver information to switch whether or not to perform the LPF processing.

By configuring in this manner, the amount of processing and power consumption can be reduced while sufficient audio characteristics are ensured by selecting, for example, whether to perform the LPF processing, in other words, an appropriate PWM conversion method, according to the sound source information, the driver information, and the output value of the amplification unit 63. In different terms, the amount of processing and power consumption can be reduced while the audio characteristics (audio performance) are dynamically optimized.

### Configuration Example of Computer

Incidentally, a series of the above-described pieces of processing can be executed by hardware as well and also can be executed by software. In a case where the series of pieces of the processing is executed by software, a program constituting the software is installed in a computer. Herein, the computer includes a computer incorporated into dedicated hardware, a computer capable of executing various functions when installed with various programs, for example, a general-purpose personal computer, and the like.

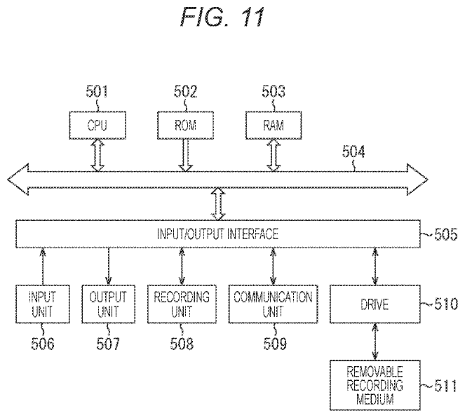

FIG. 11 is a block diagram illustrating a hardware configuration example of a computer that executes the aforementioned series of pieces of the processing using a program.

In the computer, a central processing unit (CPU) 501, a read only memory (ROM) 502, and a random access memory (RAM) 503 are interconnected through a bus 504.

Moreover, an input/output interface 505 is connected to the bus 504. An input unit 506, an output unit 507, a recording unit 508, a communication unit 509, and a drive 510 are connected to the input/output interface 505.

The input unit 506 includes a keyboard, a mouse, a microphone, an image pickup element, and the like. The output unit 507 includes a display, a speaker, and the like. The recording unit 508 includes a hard disk, a non-volatile memory, and the like. The communication unit 509 includes a network interface and the like. The drive 510 drives a removable recording medium 511 such as a magnetic disk, an optical disc, a magneto-optical disk, or a semiconductor memory.

In the computer configured as described above, for example, the aforementioned series of pieces of the processing is performed in such a manner that the CPU 501 loads a program recorded in the recording unit 508 into the RAM 503 via the input/output interface 505 and the bus 504 to execute.

For example, the program executed by the computer (CPU 501) can be provided by being recorded in the removable recording medium 511 serving as a package medium or the like. Furthermore, the program can be provided via a wired or wireless transmission medium such as a local area network, the Internet, or digital satellite broadcasting.

In the computer, the program can be installed to the recording unit 508 via the input/output interface 505 by mounting the removable recording medium 511 in the drive 510. The program can be also installed to the recording unit 508 via a wired or wireless transmission medium when received by the communication unit 509. As an alternative manner, the program can be installed to the ROM 502 or the recording unit 508 in advance.

Note that, the program executed by the computer may be a program in which the processing is performed along the time series in accordance with the order described in the present description, or alternatively, may be a program in which the processing is performed in parallel or at a necessary timing, for example, when called.

Furthermore, the embodiments according to the present technology are not limited to the above-described embodiments, and a variety of modifications can be made without departing from the scope of the present technology.

For example, the present technology can employ a cloud computing configuration in which one function is divided and allocated to a plurality of devices so as to be processed in coordination thereamong via a network.

Furthermore, the respective steps described in the aforementioned flowcharts can be executed by a plurality of devices each taking a share thereof as well as executed by a single device.

Moreover, in a case where a plurality of pieces of processing is included in one step, the plurality of pieces of the processing included in one step can be executed by a plurality of devices each taking a share thereof as well as executed by a single device.

Additionally, the present technology can be configured as described below.

(1)

A signal processing device including:

a low-pass filter that performs filter processing on a pulse density modulation (PDM) signal; and

a pulse width modulation (PWM) conversion unit that performs PWM conversion on a multibit signal obtained by the filter processing and generates a PWM signal.

(2)

The signal processing device according to (1), further including

an amplification unit that amplifies the PWM signal and also drives a reproduction device on the basis of the PWM signal after the amplification.

(3)

The signal processing device according to (2), further including

an analysis unit that designates a number of taps of the low-pass filter on the basis of a sampling frequency of the PDM signal and a clock frequency of a master clock for driving the PWM conversion unit.

(4)

The signal processing device according to (3), in which

the analysis unit designates a tap coefficient of the low-pass filter on the basis of the sampling frequency and the clock frequency.

(5)

The signal processing device according to (3) or (4), further including

a switching unit that switches whether to supply the PDM signal to the PWM conversion unit or to supply the multibit signal to the PWM conversion unit.

(6)

The signal processing device according to (5), in which

the analysis unit controls switching by the switching unit on the basis of an output to the reproduction device from the amplification unit.

(7)

The signal processing device according to (5) or (6), in which

the analysis unit controls switching by the switching unit on the basis of information regarding the reproduction device.

(8)

The signal processing device according to any one of (3) to (7), in which

the analysis unit controls the PWM conversion by the PWM conversion unit according to a drive scheme of the reproduction device.

(9)

A signal processing method performed by a signal processing device,

the signal processing method including:

performing filter processing on a PDM signal with a low-pass filter; and

performing a PWM conversion on a multibit signal obtained by the filter processing and generating a PWM signal.

(10)

A program that causes a computer to execute processing including:

a step of performing filter processing on a PDM signal with a low-pass filter; and

a step of performing PWM conversion on a multibit signal obtained by the filter processing and generating a PWM signal.

### REFERENCE SIGNS LIST

51 Signal processing device
52 Headphones
61 Low-pass filter
62 PWM conversion unit
63 Amplification unit
71 Speaker
161 Switch
162 Analysis unit

1. A signal processing device comprising:
a low-pass filter that performs filter processing on a pulse density modulation (PDM) signal; and
a pulse width modulation (PWM) conversion unit that performs PWM conversion on a multibit signal obtained by the filter processing and generates a PWM signal.

2. The signal processing device according to claim 1, further comprising
an amplification unit that amplifies the PWM signal and also drives a reproduction device on a basis of the PWM signal after the amplification.

3. The signal processing device according to claim 2, further comprising
an analysis unit that designates a number of taps of the low-pass filter on a basis of a sampling frequency of the PDM signal and a clock frequency of a master clock for driving the PWM conversion unit.

4. The signal processing device according to claim 3, wherein
the analysis unit designates a tap coefficient of the low-pass filter on a basis of the sampling frequency and the clock frequency.

5. The signal processing device according to claim 3, further comprising
a switching unit that switches whether to supply the PDM signal to the PWM conversion unit or to supply the multibit signal to the PWM conversion unit.

6. The signal processing device according to claim 5, wherein
the analysis unit controls switching by the switching unit on a basis of an output to the reproduction device from the amplification unit.

7. The signal processing device according to claim 5, wherein
the analysis unit controls switching by the switching unit on a basis of information regarding the reproduction device.

8. The signal processing device according to claim 3, wherein
the analysis unit controls the PWM conversion by the PWM conversion unit according to a drive scheme of the reproduction device.

9. A signal processing method performed by a signal processing device,
the signal processing method comprising:
performing filter processing on a PDM signal with a low-pass filter; and
performing a PWM conversion on a multibit signal obtained by the filter processing and generating a PWM signal.

10. A program that causes a computer to execute processing comprising: a step of performing filter processing on a PDM signal with a low-pass filter; and
a step of performing PWM conversion on a multibit signal obtained by the filter processing and generating a PWM signal.
